(19) United States
(12) Patent Application Publication
(10) Pub. No.: US 2022/0124917 A1
(43) Pub. Date: Apr. 21, 2022

(54) APPARATUS FOR UTILIZING REGULATING COMPONENT FOR COMMUNICATING RADIO FREQUENCY SIGNALS

(71) Applicant: SHENZHEN SUNWAY COMMUNICATION CO., LTD., Shenzhen (CN)

(72) Inventors: Kiran VANJANI, San Diego, CA (US); Hongwei LIU, San Diego, CA (US)

(73) Assignee: SHENZHEN SUNWAY COMMUNICATION CO., LTD., Shenzhen (CN)

(21) Appl. No.: 17/072,718

(22) Filed: Oct. 16, 2020

(51) Int. Cl. H05K 5/00; G06F 1/16; H04B 1/3827

(52) U.S. Cl. CPC H05K 5/0026; H04B 1/385; G06F 1/163; H05K 5/0086

(57) ABSTRACT

The invention discloses an apparatus for using a regulating component for communicating radio frequency signals. Included is a housing, a circuit board disposed in the housing, and a regulating component coupled to the housing and connected to the circuit board through a feed component. The regulating component is used for communicating radio frequency signals in use.

### FIELD OF THE INVENTION

The invention relates to antennas, and more particularly to antennas for wearable devices.

### BACKGROUND

The statement herein only provides background information relating to the invention and does not necessarily constitute the prior art.

With the rapid development of science and technology, smart wearable devices are becoming increasingly mainstream, wherein antennas are indispensable elements of the smart wearable devices for realizing independent wireless communication. For example, multi-band antennas covering GPS/BT/Wi-Fi 2.4 GHz, 5 GHz (1500-6000 MHz) are basic elements of smart watches.

Antenna radiators configured in the wearable devices as independent parts occupy a large space in the wearable devices and affect the overall design of the wearable devices. To fulfill larger displays and greater battery capacity, it still remains a challenge to reserve the space for the antennas.

### BRIEF SUMMARY OF THE INVENTION

An apparatus for utilizing a regulating component for communicating radio frequency signals is provided. Included is a housing, a circuit board disposed in the housing, and a regulating component coupled to the housing and connected to the circuit board through a feed component. We are proposing using the existing regulating component for communicating radio frequency signals.

### BRIEF DESCRIPTION OF THE SEVERAL VIEWS OF THE DRAWINGS

FIG. 1 illustrates an apparatus for utilizing an existing regulating component for communicating radio frequency signals, in accordance with one embodiment;

FIG. 2 is a schematic diagram of a watch equipped with a regulating component, in accordance with one embodiment;

FIG. 3 is a schematic diagram of a watch equipped with a protruding regulating component, in accordance with one embodiment;

FIG. 4 is an internal structural view of FIG. 2;

FIG. 5 is an enlarged view of part A in FIG. 4;

FIG. 6 is a top view of FIG. 4;

FIG. 7 illustrates a signal diagram illustrating an antenna S-parameter, in accordance with one embodiment;

FIG. 8 illustrates a signal diagram illustrating an antenna efficiency, in accordance with one embodiment;

FIG. 9 illustrates a network architecture, in accordance with one possible embodiment;

FIG. 10 illustrates an exemplary system, in accordance with one embodiment.

### DETAILED DESCRIPTION OF THE INVENTION

FIG. 1 illustrates an apparatus 100 for utilizing an existing regulating component for communicating radio frequency (RF) signals. As shown, the apparatus 100 includes a housing 101, a circuit board 102 and a regulating component 103, wherein the circuit board 102 is disposed in the housing 101, and the regulating component 103 is coupled to the shell 101 and is connected to the regulating component 103 through a feed structure 104, so that the regulating component can be used as an antenna radiator for communicating radio frequency signals. The term “communicate” may refer to any receipt or transmission of signals. In the context of the present description, the housing 101 may include any structure that is capable of having the regulating component 103 coupled thereto. The regulating component 103 may refer to any mechanism that functions as a component for controlling a device associated with the housing.

Wherein, the apparatus 100 may be a wearable device, such as a watch (e.g. smart watch, etc.), glasses (e.g., smart glasses, etc.), a smart band, a pedometer or heat rate monitor. Of course, other embodiments are contemplated where the apparatus 100 may be a phone (e.g., smart phone, etc.), a personal digital assistant (PDA) or any other devices.

In one embodiment, the regulating component 103 is movably (e.g., slidably, etc.) coupled to the housing 101 and is configured to generate a signal in response to a movement of the regulating component 103. For example, in one embodiment, the regulating component 103 is operable such that a signal is generated in response to a depression (e.g., manual depression, etc.) of the regulating component 103. Such signal could control at least one function of the apparatus 100. In such embodiment, the regulating component 103 may be a push button or a rocker switch (e.g., rocker switch with a selection function such as volume control). In other embodiments, the regulating component 103 may be rotatably (e.g., so as to be windable. etc.) coupled to the housing 101 and interact with internal mechanical components (e.g., winding spring, etc.) in the housing 101 to generate a signal, and in such embodiment, the regulating component 103 may be a rotary knob. Of course, any combination of different movements may be implemented for allowing any type of manipulation, in various embodiments. Of course, the regulating component 103 may be configured for only aesthetic purpose.

In an optional embodiment, the regulating component and the housing have one, two or more contact points therebetween.

With continuing reference to FIG. 1, a feed point 105 is disposed at a position of the regulating component 103 in a lengthwise direction and may be configured at any position of the regulating component 103 in the lengthwise direction, and the circuit board 102 is connected to the feed point 105 through the feed component 104 such that the regulating component 103 may be used as an antenna radiator. To further improve the antenna performance, the regulating component 103 may be made of a conductive material. Of course, in other embodiments, the regulating component 103 may be made of a conductive material and an insulating material. In one embodiment, the feed component 104 is a single-layer or multi-layer flexible feed line. To facilitate antenna matching and radiation, the flexible feed line may include discrete components or wires. In other optional embodiments, the feed component 104 may be a C-clip or a pogo pin.

More illustrative information will now be set forth regarding various optional architectures and uses in which the foregoing method may or may not be implemented, per the desires of the user. It should be strongly noted that the following information is set forth for illustrative purposes and should not be construed as limiting in any manner. Any of the following features may be optionally incorporated with or without the exclusion of other features described.

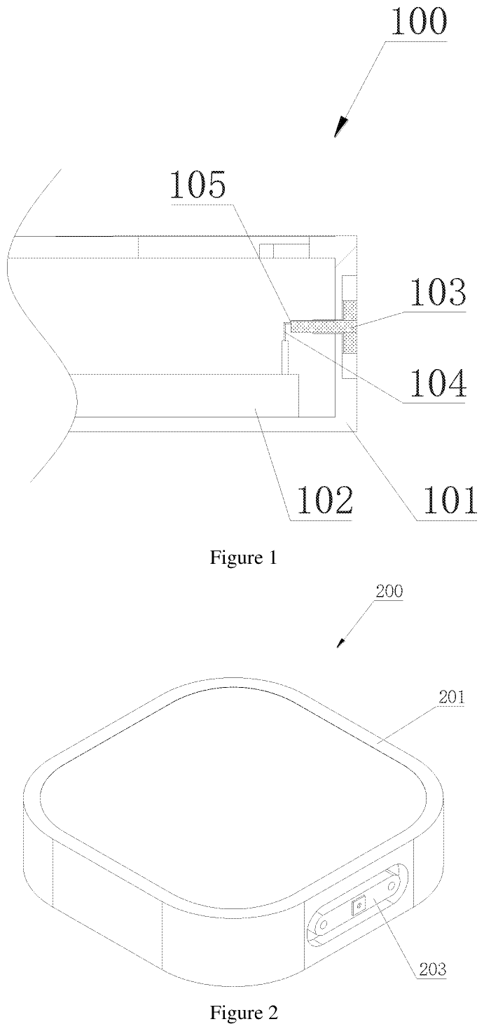

FIG. 2 is a watch 200 equipped with a regulating component. As an option, the watch may be implemented in the context of any one or more of the embodiments set forth in any previous and/or subsequence figure (s) and/or description thereof. Of course, the watch may be implemented in the context of any desired environment.

As shown in FIG. 2, the watch 200 includes a square-faced housing 201 with the regulating component 203 on a periphery thereof. In this embodiment, the housing 201 of the watch is square. In other embodiments, the housing 201 may be round, rectangular or oval or any other shapes.

Further, while only one regulating component 203 is shown in the present embodiment, it should be noted that other embodiments are contemplated with more than one regulating component 203 which are connected to the circuit board through the feed component, and each of regulating components may be used as a radiator of an antenna with a different frequency band. In embodiments where multiple regulating components 203 are incorporated, these regulating components 203 may be similarly or differently constructed (e.g., one or more rotatable and one or more depressible). In one embodiment where multiple regulating components 203 are incorporated, one regulating component 203 is used as an antenna radiator, and the other regulating components 203 may be coupled to a ground region of the circuit board to improve the antenna performance such as a ground parasitic structure. Further, the multiple regulating components 203 are closely configured to improve the radiated antenna performance.

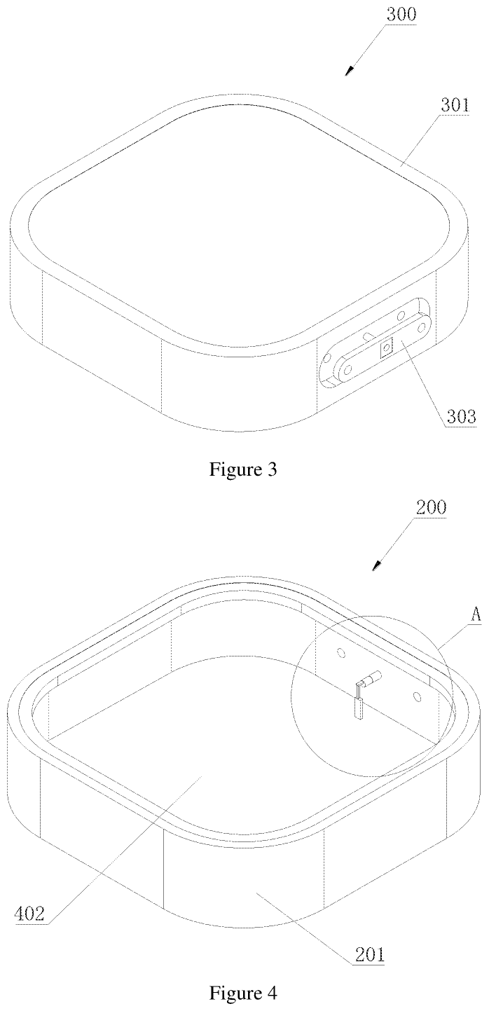

In this embodiment, the regulating component 203 is embedded in the housing 201, and a side, towards an outside of the housing 201, of the regulating component 203 is flush with a peripheral surface of the housing 201. FIG. 3 illustrates a watch 300 equipped with a protruding regulating component. As shown in FIG. 3, in another embodiment, an end, towards the outside of the housing 301, of the regulating component 303 extends out of a periphery of the housing 301. Of course, in other embodiments, the regulating component may be a protruding small button or is flush with the peripheral surface of the housing, and is partially or entirely coupled to the housing.

In this embodiment, the regulating component 203 may be in a shape illustrated by FIG. 2. In other embodiments, the regulating component 203 may be oval, round or cylindrical or in other regular or irregular shapes and may have different dimensions in three dimensional directions (X-axis direction, Y-axis direction and Z-axis direction). Further, in optional embodiments, the regulating component 203 may be of a solid structure, a hollow or mesh structure.

In one optional embodiment, the housing 201 is made of a conductive material (e.g., stainless steel, aluminum, etc.), and a side, provided with the regulating component 203, of the housing 201 is covered with an insulative material (such as plastic). In other embodiments where the housing 201 is made of a conductive material, a spacer 207 made of an insulative material may be disposed between the regulating component 203 and the housing 201 such that electrical contact between the housing 201 and the regulating component 203 is avoided. Of course, in other embodiments, the housing 201 may also be made of an insulative material (such as plastic ABS).

FIG. 4 is an internal structural view of the watch 200 in FIG. 2 after a transparent surface or dial plate or a display component and a battery or electronic device mounted on a circuit board are removed. As shown, a circuit board 402 is mounted in the housing 201. In one embodiment, the circuit board 402 is a PCB made of a copper-layer, single-layer or multi-layer flexible circuit, and the circuit on the PCB is used to provide any required function associated with the use of the watch 200.

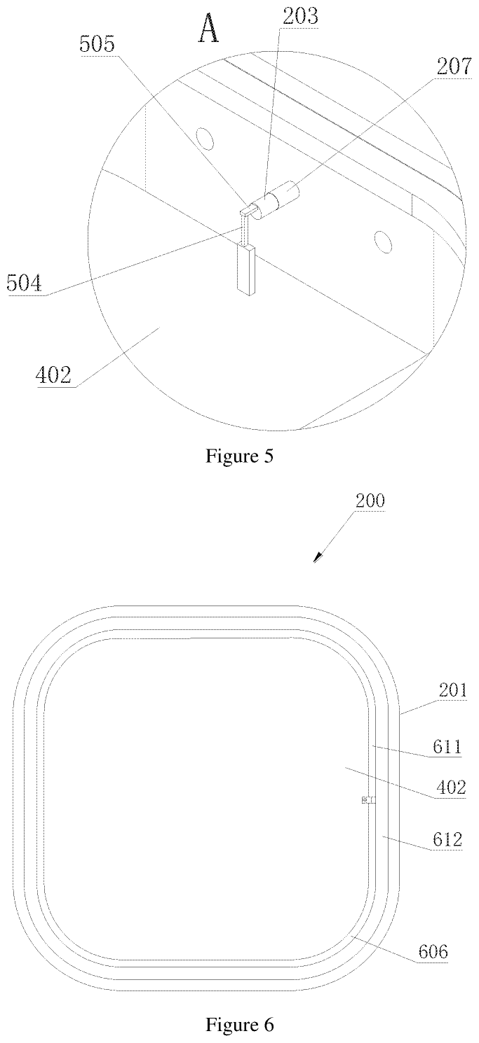

FIG. 5 is an enlarged view of part A in FIG. 4. As shown, the regulating component 203 has a feed point 505, and the circuit board 402 is connected to the feed point 505 through a feed component 504. In this embodiment, the feed point 505 is disposed at a position illustrated in FIG. 5. In other embodiment, the feed point 505 may be disposed at other positions of the regulating component 203 in a lengthwise direction. In optional embodiments, the feed component 504 may be a single-layer or multi-layer flexible feed line, a C-clip or a pogo pin.

FIG. 6 is a top view of FIG. 4. As shown, the housing 201 comprises a back shell 611 and a frame 612, wherein the back shell 611 is configured to abut against the skin of a user, the frame 612 is disposed on the back shell 611, the circuit board 402 is disposed in a spaced defined by the frame 611 and the back shell 612, and to fulfill better radiation, an insulative region 606 is disposed between the circuit board 402 and the frame 612. In this embodiment, the insulative region 606 may be filled with air. In other embodiments, the insulative region 606 may be filled with insulative materials such as plastic or ceramic.

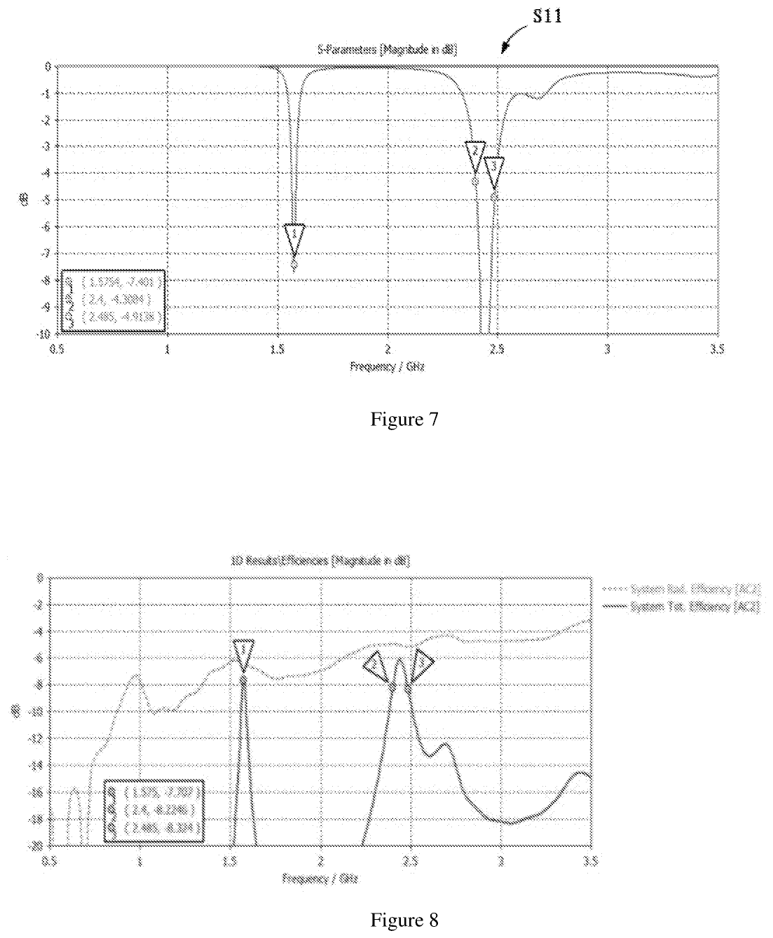

FIG. 7 illustrates a signal diagram illustrating an antenna S-parameter, in accordance with one embodiment, wherein S 11 is input return loss of the antenna in discussion vs operating frequency and the degree of matching with 50 Ohms are basically illustrated. In this embodiment, the antenna has been optimized for GPS (1.575 GHz) and WiFi 2.4 GHz (2.4-2.485 GHz).

FIG. 8 illustrates a signal diagram illustrating an antenna efficiency, in accordance with one embodiment, wherein the dotted line refers to system radiation efficiency, and the full line refers to system total efficiency. In this embodiment, again the antenna has been optimized for GPS (1.575 GHz) and WiFi 2.4 GHz (2.4-2.485 GHz).

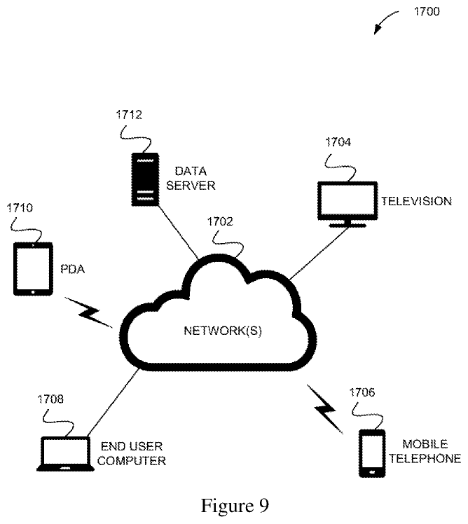

FIG. 9 illustrates a network architecture 1700. For example, in one embodiment, the watch from one or more of the previous embodiments may be implemented in the context of the current network architecture 1700.

As shown, at least one network 1702 is provided. In the context of the present network architecture 1700, the network 1702 may take any form including, but not limited to, a telecommunications network, a local area network (LAN), a wireless network, a wide area network (WAN) such as the Internet, etc. While only one network is shown, it should be understood that two or more similar or different networks 1702 may be provided.

Coupled to the network 1702 is a plurality of devices. For example, a server computer 1712 and an end user computer 1708 may be coupled to the network 1702 for communication purposes. Such end user computer 1708 may include a desktop computer, a lap-top computer, and/or any other type of logic. Still yet, various other devices may be coupled to the network 1702 including a personal digital assistant (PDA) device 1710, a mobile phone device 1706, a television 1704, etc.

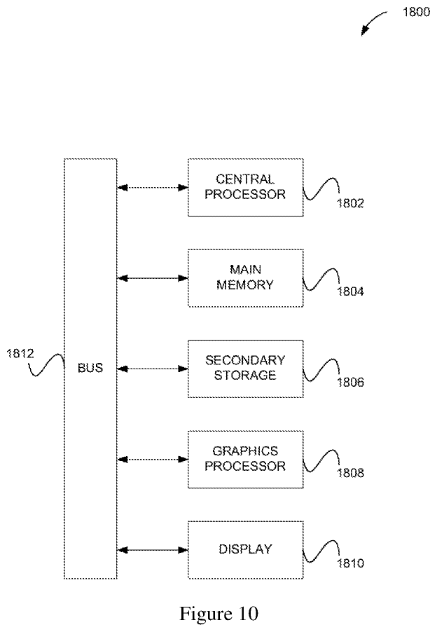

FIG. 10 illustrates an exemplary system 1800, in accordance with one embodiment. As an option, the system 1800 may be implemented in the context of any of the devices of the network architecture 1700 of FIG. 9, including a watch disclosed in one or more of the embodiments described hereinabove. Just by way of example, the apparatus 100 of FIG. 1 and/or the watch 200 of FIG. 2 may be equipped with one or more of the components of the system 1800. Of course, the system 1800 may be implemented in any desired environment.

As shown, a system 1800 is provided including at least one central processor 1802 which is connected to a communication bus 1812. The system 1800 also includes a main memory 1804 [e.g., random access memory (RAM), etc.]. The system 1800 also includes a graphics processor 1808 and a display 1810.

The system 1800 may also include a secondary storage 1806. The secondary storage 1806 includes, for example, a hard disk drive and/or a removable storage drive, representing a floppy disk drive, a magnetic tape drive, a compact disk drive, etc. The removable storage drive reads from and/or writes to a removable storage unit in a well-known manner.

Computer programs, or computer control logic algorithms, may be stored in the main memory 1804, the secondary storage 1806, and/or any other memory, for that matter. Such computer programs, when executed, enable the system 1800 to perform various functions (as set forth above, for example). Memory 1804, storage 1806 and/or any other storage are possible examples of tangible computer-readable media.

It is noted that the techniques described herein, in an aspect, are embodied in executable instructions stored in a computer readable medium for use by or in connection with an instruction execution machine, apparatus, or device, such as a computer-based or processor-containing machine, apparatus, or device. It will be appreciated by those skilled in the art that for some embodiments, other types of computer readable media are included which may store data that is accessible by a computer, such as magnetic cassettes, flash memory cards and digital video disks. Bernoulli cartridges, random access memory (RAM), read-only memory (ROM), and the like.

As used here, a “computer-readable medium” includes one or more of any suitable media for storing the executable instructions of a computer program such that the instruction execution machine, system, apparatus, or device may read (or fetch) the instructions from the computer readable medium and execute the instructions for carrying out the described methods. Suitable storage formats include one or more of an electronic, magnetic, optical and electromagnetic formats. A non-exhaustive list of a conventional exemplary computer readable medium includes: a portable computer diskette; a RAM; a ROM; an erasable programmable read only memory (EPROM or flash memory); optical storage devices, including a portable compact disc (CD), a portable digital video disc (DVD), a high definition DVD (HD-DVD) TM3), a BLU-RAY disc; and the like.

It should be understood that arrangement of components illustrated in the Figures described are exemplary and that other arrangements are possible. It should also be understood that the various system components (and means) defined by the claims, described below, and illustrated in the various block diagrams represent logic components in some systems configured according to the subject matter disclosed herein.

For example, one or more of these system components (and means) may be realized, in whole or in part, by at least some of the components illustrated in the arrangements illustrated in the described figures. In addition, while at least one of these components are implemented at least partially as an electronic hardware component, and therefore constitutes a machine, the other components may be implemented in software that when included in an execution environment constitutes a machine, hardware, or a combination of software and hardware.

More particularly, at least one component of one or more embodiments may be implemented at least partially as an electronic hardware component, such as an instruction execution machine (e.g., a processor-based or processor-containing machine) and/or as specialized circuits or circuitry (e.g., discrete logic gates interconnected to perform a specialized function). Other components may be implemented in software, hardware, or a combination of software and hardware. Moreover, some or all these other components may be combined, some may be omitted altogether, and additional components may be added while still achieving the functionality described herein. Thus, the subject matter described herein may be embodied in many different variations, and all such variations are contemplated to be within the scope of one or more embodiments.

In the description above, the subject matter is described with reference to acts and symbolic representations of operations that are performed by one or more devices, unless indicated otherwise. As such, it will be understood that such acts and operations, which are at times referred to as being computer-executed, include the manipulation by the processor of data in a structured form. This manipulation transforms the data or maintains it at locations in the memory system of the computer, which reconfigures or otherwise alters the operation of the device in a manner wall understood by those skilled in the art. The data is maintained at physical locations of the memory as data structures that have particular properties defined by the format of the data. However, while the subject matter is being described in the foregoing context, it is not meant to be limiting as those of skill in the art will appreciate that various of the acts and operations described hereinafter may also be implemented in hardware.

To facilitate an understanding of the subject matter described herein, many aspects are described in terms of sequences of actions. At least one of these aspects defined by the claims is performed by an electronic hardware component. For example, it will be recognized that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a”, “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated therein, and each separate value is incorporated into the specification as if it were individually recited herein. Furthermore, the foregoing description is for the purpose of illustration only, and not for the purpose of limitation, as the scope of protection sought is defined by the claims as set forth hereinafter together with any equivalents thereof entitled to. The use of any or all examples, or exemplary languages (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions are bright about that result. No language in the specification should be construed as indicating any non-claimed element as essential to the practice of the invention as claimed.

The embodiments described therein included the one or more modes known to the inventor for carrying out the claimed subject matter. Of course, variations of those embodiments will become apparent to those of ordinary skilled in the art upon reading the foregoing description. The inventor expects skilled artisans to employ such variations as appropriate, and the inventor intends for the claimed subject matter to be practiced otherwise than as specifically described therein. Accordingly, this claimed subject matter includes all modifications and equivalents of the subject matter recited in the claims appended hereinto as permitted by applicable law. Moreover, any combination of the above-described elements in all possible variations thereof is encompassed unless otherwise indicated therein or otherwise clearly contradicted by context.

1. An apparatus, comprising:
a housing;
a circuit board disposed in the housing; and
a regulating component coupled to the housing, connected to the circuit board through a feed component, and used for transmitting radio frequency signals.

2. The apparatus according to claim 1, wherein the regulating component is rotatably coupled to the housing.

3. The apparatus according to claim 2, being configured to generate a signal in response to a movement of the regulating component.

4. The apparatus according to claim 1, wherein a feed point is disposed at a position of the regulating component in a lengthwise direction, and the circuit board is connected to the feed point through the feed component.

5. The apparatus according to claim 1, wherein the feed component is a single-layer or multi-layer feed line, a C-clip or a pogo pin.

6. The apparatus according to claim 1, wherein the circuit board is a PCB which is made of a copper-layer, single-layer or multi-layer flexible circuit.

7. The apparatus according to claim 1, wherein the regulating component is embedded in the housing, and a side, towards an outside of the housing, of the regulating component is flush with a peripheral surface of the housing; or, an end, towards the outside of the housing, of the regulating component extends out of a periphery of the housing.

8. The apparatus according to claim 1, wherein the regulating component and the housing have one, two or more contact points therebetween.

9. The apparatus according to claim 1, wherein the housing comprises a back shell and a frame disposed on the back shell, the circuit board is disposed in a space defined by the frame and the back shell, and an insulative region is disposed between the circuit board and the frame.

10. The apparatus according to claim 1, wherein a spacer is disposed between the regulating component and the housing and is made of an insulative material.

11. The apparatus according to claim 1, wherein the housing is made of a conductive material or an insulative material.

12. The apparatus according to claim 1, wherein the regulating component is made of a conductive material or is made of a conductive material and an insulative material.

13. The apparatus according to claim 1, wherein the regulating component is oval, round, rectangular or cylindrical, or is in other regular or irregular shapes.

14. The apparatus according to claim 1, wherein the regulating component is of a solid structure, a hollow structure or a mesh structure.

15. The apparatus according to claim 1, wherein one, two or more regulating components are configured.

16. The apparatus according to claim 1, wherein the regulating component is a push button, a rotary knob or a rocker switch.

17. The apparatus according to claim 1, being a wearable device.
